(19) United States
(12) Patent Application Publication
(10) Pub. No.: US 2006/0086985 A1
(43) Pub. Date: Apr. 27, 2006

(54) Semiconductor device

(76) Inventor: Motoya Kishida, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/251,858

(22) Filed: Oct. 18, 2005

(30) Foreign Application Priority Data
Oct. 18, 2004 (JP) 2004-303281

(51) Int. Cl. H01L 29/76

(52) U.S. Cl. 257/365

(57) ABSTRACT

A semiconductor device includes first integrated circuit comprising first to third MOSFET having same channel type, and first to third MOSFETs including gate electrode and gate sidewall insulating film on sidewall of gate electrode, and distance between gate electrodes of first and second MOSFETs, and distance between gate electrodes of first and third MOSFETs being same first distance, and a second integrated circuit comprising fourth MOSFET of which at least one of film thickness of gate insulating film and channel type is different from those of first MOSFET, fifth MOSFET and sixth MOSFET, fourth to sixth MOSFETs having same channel type, and fourth to sixth MOSFETs including gate electrode and gate sidewall insulating film on sidewall of gate electrode, and distance between gate electrodes of fourth and fifth MOSFETs, and distance between gate electrodes of fourth and sixth MOSFETs being same second distance which is different from first distance.

### CROSS-REFERENCE TO RELATED APPLICATIONS

This application is based upon and claims the benefit of priority from prior Japanese Patent Application No. 2004-303281, filed Oct. 18, 2004, the entire contents of which are incorporated herein by reference.

### BACKGROUND OF THE INVENTION

1. Field of the Invention

The present invention relates to a semiconductor device including MOSFETs.

2. Description of the Related Art

One of the problems which have become obvious accompanying the progress in scaling MOSFETs is deterioration in the reliability of gate oxide film which is brought about due to thermal electrons generated by a concentration of electric fields onto gate electrode edge being poured into the gate oxide film.

In order to avoid this problem, there has been proposed a so-called LDD (Lightly Doped Drain) structure which is formed such that impurities whose concentration is relatively low are implanted into source/drain regions of gate edges, and impurities whose concentration is higher are implanted into regions away from the gate edges in order to decrease the resistance.

The LDD architecture is formed by implanting impurities having relatively low concentration in the source/drain regions of the gate edges after a gate electrode is formed, and thereafter, forming gate sidewall insulating film (spacer) on a sidewall of the gate electrode, and implanting impurities having high concentration. Accordingly, it can be understood that the width of the spacer is extremely important parameter for determining the width of the LDD region.

The spacer is generally formed as follows (Jpn. Pat. Appln. KOKAI Publication No. 2003-163215). That is, the spacer is formed by depositing a silicon oxide film or a silicon nitride film (LPCVD insulating film) on an entire surface by LPCVD process, and thereafter, etching the LPCVD insulating film aeolotropically (anisotropically) by RIE (Reactive Ion Etching) process.

Here, the reason why the LPCVD process is used is as follows. An LPCVD process is excellent in sidewall coverage as compared with plasma CVD process or the like. Therefore, an insulating film suitable for forming spacers is formed by using LPCVD process.

However, in MOSFETs fallen under the realm of nano-order in recent years, the following problem has come to the front with respect to the conventional method for forming the spacer by LPCVD process.

When a film thickness of the spacer (spacer film thickness) is made about several tens of nm, a so-called pattern density difference that the film thicknesses on gate sidewall of an LPCVD insulating film is varied. One of the reasons why the pattern density difference is generated is that an aspect determined by a height of gate electrode and a space between gate electrodes has been made higher. The variation in the film thicknesses on the gate sidewall of the LPCVD insulating film brings about a fluctuation in an LLD structure. Therefore, the variation in the film thicknesses on the gate sidewall has a significant influence on the MOSFET property.

A system LSI has n-channel and p-channel type MOSFETs. An optimum spacer film thickness differs with respect to the n-channel MOSFET and p-channel MOSFET. Moreover, even in MOSFETs of the same channel type, if power supply voltages to be used are different from one another, the thicknesses of the gate oxide films are different from one another. Accordingly, even in MOSFETs of the same channel type, the optimum spacer film thickness is different from each other in some cases. That is, there is a plurality of optimum spacer film thicknesses in a system LSI.

The variation of the spacer film thicknesses depending on the layout (pattern density difference) of the MOSFETs in the system LSI amplifies a fluctuation in the LDD structure of each MOSFET. This has been a factor disturbing the function of the system LSI.

### BRIEF SUMMARY OF THE INVENTION

A semiconductor device according to an aspect of the present invention comprises a semiconductor substrate; a first integrated circuit provided on the semiconductor substrate, the first integrated circuit comprising a first MOSFET, a second MOSFET disposed at one side of the first MOSFET, and a third MOSFET disposed at other side of the first MOSFET, the first, second, and third MOSFETs having same channel type, and each of the first, second, and third MOSFETs including gate electrode and gate sidewall insulating film provided on a sidewall of the gate electrode, and a distance between the gate electrodes of the first and second MOSFETs, and a distance between the gate electrodes of the first and third MOSFETs being same first distance; and a second integrated circuit provided on the semiconductor substrate, the second integrated circuit comprising a fourth MOSFET of which at least one of a film thickness of a gate insulating film and a channel type is different from those of the first MOSFET, a fifth MOSFET disposed at one side of the fourth MOSFET, and a sixth MOSFET disposed at other side of the fourth MOSFET, the fourth, fifth, and sixth MOSFETs having the same channel type, and each of the fourth, fifth, and sixth MOSFETs including gate electrode and gate sidewall insulating film provided on sidewall of gate electrode, and a distance between the gate electrodes of the fourth and fifth MOSFETs, and a distance between the gate electrodes of the fourth and sixth MOSFETs being same second distance which is different from the first distance.

A semiconductor device according to another aspect of the present invention comprises a semiconductor substrate; and an integrated circuit provided on the semiconductor substrate, the integrated circuit comprising a first line-up of first MOSFETs each having a first characteristic and a second line of second MOSFETs each having a second characteristic which is different from the first characteristic, each of the first and second MOSFETs includes gate electrode and gate sidewall insulating film provided on a sidewall of the gate electrode, the gate sidewall insulating film of the first MOSFET having a thickness corresponding to the first characteristic, and the gate sidewall insulating film of the second MOSFET having a thickness corresponding to the second characteristic.

### BRIEF DESCRIPTION OF THE SEVERAL VIEWS OF THE DRAWING

FIG. 1 is a diagram schematically showing a semiconductor device according to an embodiment of the present invention;

FIG. 2 is a cross-sectional view showing MOSFETs in an nMOS integrated circuit in the embodiment;

FIG. 3 is a cross-sectional view showing MOSFETs in a pMOS integrated circuit in the embodiment;

FIG. 4 is a cross-sectional view showing MOSFETs in a comparative example nMOS integrated circuit;

FIG. 5 is a cross-sectional view showing MOSFETs in a comparative example pMOS integrated circuit;

FIG. 6 is a cross-sectional view showing a manufacturing method for the semiconductor device according to the embodiment;

FIG. 7 is a cross-sectional view showing a manufacturing method for the semiconductor device according to the embodiment following FIG. 6;

FIG. 8 is a cross-sectional view showing a manufacturing method for the semiconductor device according to the embodiment following FIG. 7;

FIG. 9 is a cross-sectional view showing a manufacturing method for the semiconductor device according to the embodiment following FIG. 8;

FIG. 10 is a plan view showing regions covered with a resist formed in the process of FIG. 6;

FIG. 11 is a plan view showing regions covered with a resist formed in the process of FIG. 8;

FIG. 12 is a plan view showing regions covered with another resist formed in the process of FIG. 8;

FIG. 13 is a plan view showing MOSFETs (distances between spacers on active region=distances between spaces on isolation region) in the integrated circuits in the embodiment;

FIG. 14 is a plan view showing other MOSFETs (distances between spacers on active region≠distances between spaces on isolation region) in the integrated circuits in the embodiment;

FIG. 15 is a cross-sectional view showing a manufacturing method for the semiconductor device according to another embodiment;

FIG. 16 is a cross-sectional view showing a manufacturing method for the semiconductor device according to the embodiment following FIG. 15;

FIG. 17 is a cross-sectional view showing a manufacturing method for the semiconductor device according to the embodiment following FIG. 16; and

FIG. 18 is a cross-sectional view showing a manufacturing method for the semiconductor device according to the embodiment following FIG. 17.

### DETAILED DESCRIPTION OF THE INVENTION

Hereinafter, an embodiment of the present invention will be described with reference to the drawings.

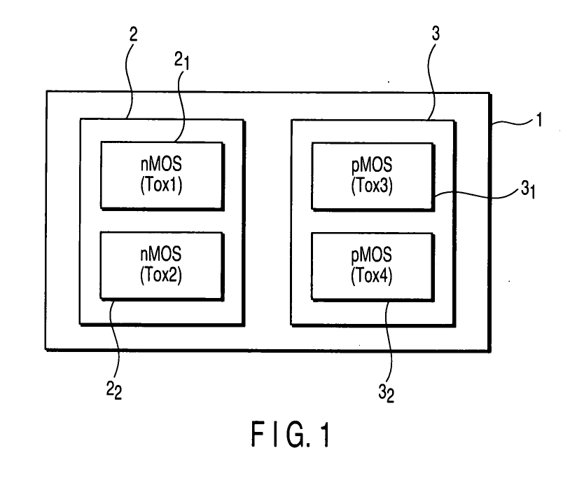

FIG. 1 is a diagram schematically showing a semiconductor device according to an embodiment of the present invention.

In FIG. 1, reference numeral 1 denotes a semiconductor device, and the semiconductor device 1 has an nMOS integrated circuit 2 including a plurality of n-channel type MOSFETs, and a pMOS integrated circuit 3 including a plurality of p-channel type MOSFETs.

The nMOS integrated circuit 2 and the pMOS integrated circuit 3 are integrated circuits in, for example, a system LSI, and do not comprises a circuit including gate electrodes repeatedly disposed at intervals of minimum dimension (for example, memory cell circuits in a storage device such as a DRAM or the like) and a peripheral circuit thereof. Or, the nMOS integrated circuit 2 and the pMOS integrated circuit 3 are logic ICs or ASICs, and more specifically, those are CMOS integrated circuits in those integrated circuits. The former logic ICs are circuits in a system LSI in some cases.

The nMOS integrated circuit 2 comprises a first nMOS integrated circuit 2₁ including a plurality of n-channel type MOSFETs in which the film thicknesses of the gate oxide films are Tox1 and a second nMOS integrated circuit 2₂ including a plurality of n-channel type MOSFETs in which the film thicknesses of the gate oxide films are Tox2.

The PMOS integrated circuit 3 comprises a first pMOS integrated circuit 3₁ including a plurality of p-channel type MOSFETs in which the film thicknesses of the gate oxide films are Tox3 and a second pMOS integrated circuit 3₂ including a plurality of p-channel type MOSFETs in which the film thicknesses of the gate oxide films are Tox4.

In the present embodiment, the description will be carried out supposing that Tox1≠Tox2, Tox3≠Tox4, Tox1=Tox3, Tox2=Tox4. To describe more concretely, that is Tox1=Tox3=15 nm, Tox2=Tox4=4 nm. A power supply voltage of the MOSFETs of Tox1=Tox3=15 nm is 3V, and a power supply voltage of the MOSFETs of Tox2=Tox4=4 nm is 1V.

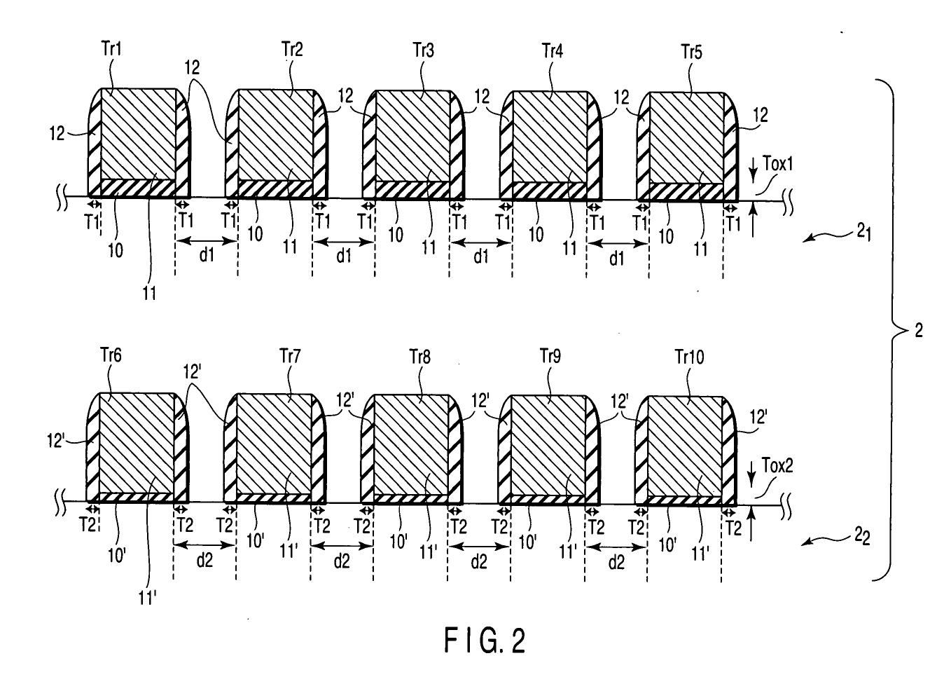

FIG. 2 is a cross-sectional view showing the MOSFETs in the nMOS integrated circuit 2 (2₁, 2₂).

In FIG. 2, reference numerals Tr1 to 5 denote n-channel type MOSFETs in the nMOS integrated circuit 2₁, and reference numerals Tr6 to 10 denote n-channel type MOSFETs in the nMOS integrated circuit 2₂, and reference numerals 10 and 10′ denote gate oxide films, and reference numerals 11 and 11′ denote gate electrodes, and reference numerals 12 and 12′ denote gate sidewall insulating films (spacers), and reference numerals d1 denote distances between the gate electrodes 11 adjacent to one another in the nMOS integrated circuit 2₁, and reference numerals d2 denote distances between the gate electrodes 11′ adjacent to one another in the nMOS integrated circuit 2₂.

The distance d1 is a distance between the right end of a MOSFET Tri (i=1, 2, 3, 4) 2 and the left end of a MOSFET Tri+1 which is at the right side thereof. In the same way, the distance d2 is a distance between the right end of a MOSFET Trj (j=6, 7, 8, 9) 2 and the left end of a MOSFET Trj+1 which is at the right side thereof.

In the present embodiment, the MOSFET Tr2 is a dummy MOSFET (dummy gate electrode section), and does not carry out transistor operations. The dummy MOSFET is provided so as to make the distances d1 between the respective MOSFETs equal to one another, and the MOSFET Tr2 is not necessarily made a dummy MOSFET. Further, the number of dummy MOSFETs is not limited to one, and may be two or more in some cases. In the same way, the MOSFET Tr7 is a dummy MOSFET provided for making the distances d2 equal to one another.

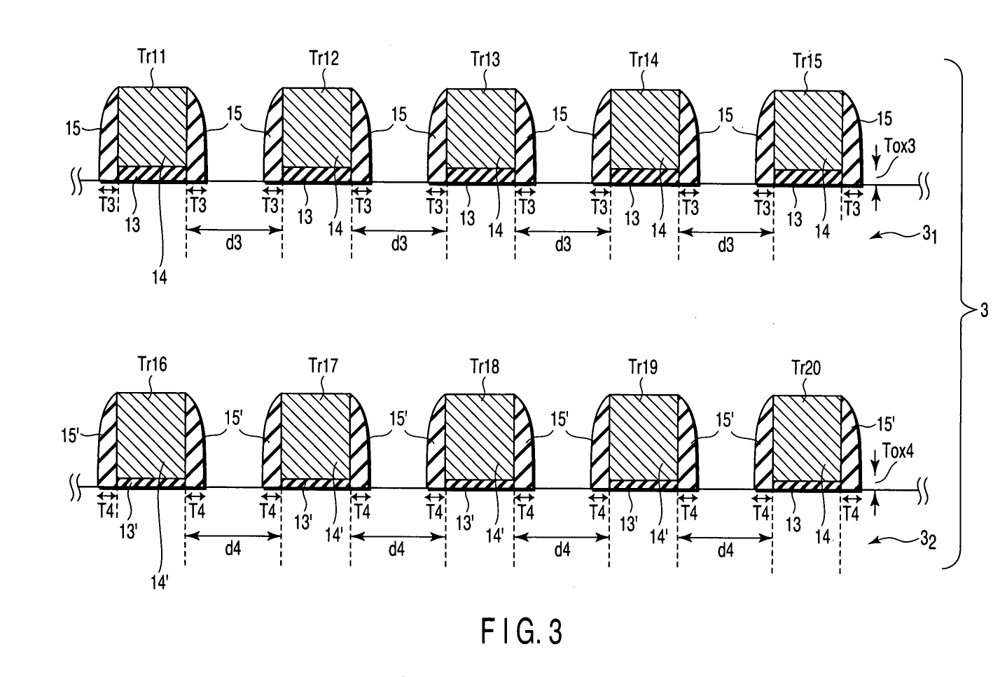

FIG. 3 is a cross-sectional view showing the MOSFETs in the PMOS integrated circuit 3 (3₁, 3₂)

In FIG. 3, reference numerals Tr11 to 15 denote p-channel type MOSFETs in the pMOS integrated circuit 3₁, and reference numerals Tr16 to 20 denote p-channel type MOSFETs in the pMOS integrated circuit 3₂, and reference numerals 13 and 13′ denote gate oxide films, and reference numerals 14 and 14′ denote gate electrodes, and reference numerals 15 and 15′ denote gate sidewall insulating films (spacers), and reference numerals d3 denote distances between the gate electrodes 14 adjacent to one another in the pMOS integrated circuit 3₁, and reference numerals d4 denote distances between the gate electrodes 14′ adjacent to one another in the pMOS integrated circuit 3₂.

Here, the distances d3 and d4 are defined as in the same way as the distances d1 and d2. The MOSFETs Tr12 and Tr17 are dummy MOSFETs in the same way as the MOSFETs Tr2 and Tr7.

In the present embodiment, distances between the respective gate electrodes in the integrated circuit 2₁ are d1 which are constant. In the same way, distances between the respective gate electrodes in the integrated circuit 2₂ are d2 which are constant. Further, as shown in FIG. 3, in the present embodiment, distances between the respective gate electrodes in the integrated circuit 3₁ are d3 which are constant. In the same way, distances between the respective gate electrodes in the integrated circuit 3₂ are d4 which are constant.

The distances d1 to d4 between the gate electrodes in the respective integrated circuits 2₁, 2₂, 3₁, and 3₂ have specific values determined in accordance with a channel type of a MOSFET and a film thickness of a gate oxide film. Generally, a distance between the gate electrodes in a case of an n-channel is shorter than that in a case of a p-channel, and the thinner the film thickness of a gate oxide film is, the shorter the distance between gate electrodes is. Moreover, the film thicknesses T1 to T4 of the spacers 12, 12′, 15, and 15′ in the respective integrated circuit 2₁, 2₂, 3₁, and 3₂ as well are respectively constant in the same way as the distances d1 to d4 between the gate electrodes. The film thicknesses T1 to T4 are, as shown in FIG. 2 and FIG. 3, sizes in the direction of the channel length of portions of the spacers 12, 12′, 15, and 15′. The portions contact on a surface of the substrate.

Concretely, that is d1=150 nm, d2=200 nm, d=250 nm, and d4=300 nm. Due to the d1 to d4 being set on the values, optimum spacer film thicknesses which are, for example, T1=20 nm, T2=23 nm, T3=26 nm, and T4=28 nm can be selected. In other words, the spacer film thicknesses T1 and T3 of the MOS integrated circuits 2₁ and 3₁ whose power supply voltages are 3V and the spacer film thicknesses T2 and T4 of the MOS integrated circuits 2₂ and 3₂ whose power supply voltages are 1V can be respectively set to optimum values.

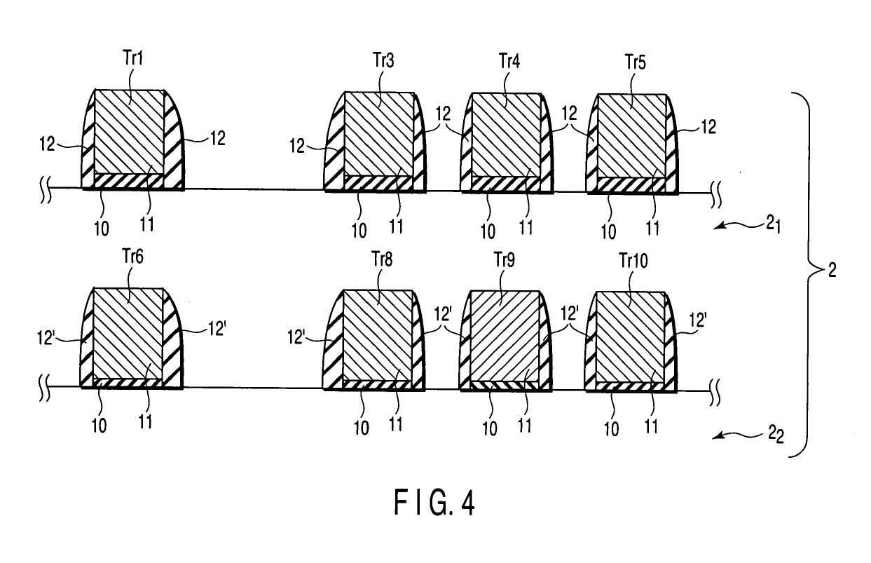

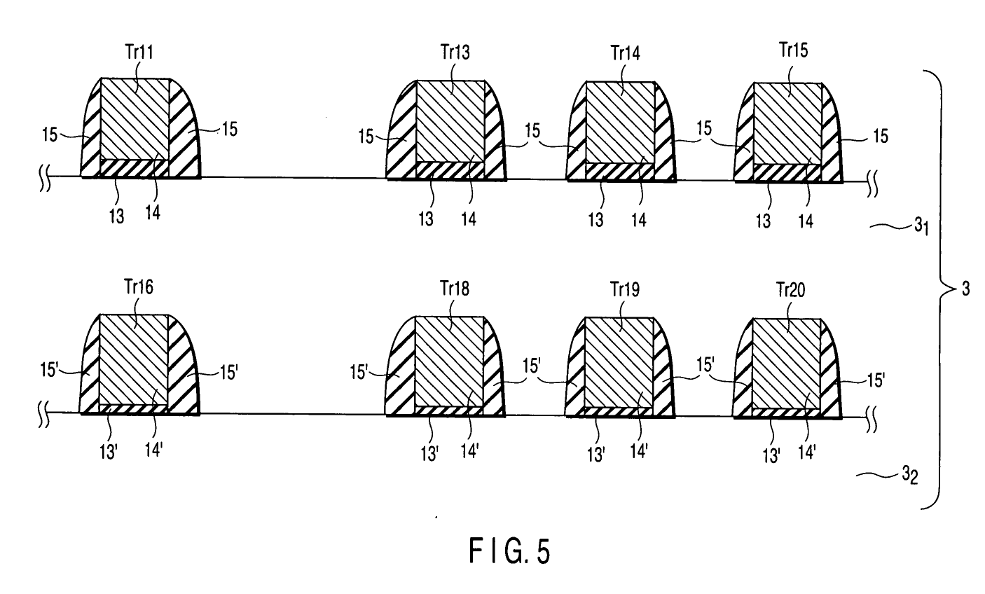

The cross-sectional views of the comparative example nMOS integrated circuit and pMOS integrated circuit which correspond to FIG. 2 and FIG. 3 of the present embodiment are shown in FIG. 4 and FIG. 5. Note that portions corresponding to those in FIG. 2 and FIG. 3 are denoted by the same reference numerals in FIG. 2 and FIG. 3.

As shown in FIG. 4 and FIG. 5, in cases of the nMOS integrated circuit 2 and pMOS integrated circuit 3, since there are no dummy MOSFETs (MOSFETs Tr2, Tr7, Tr12, and Tr17), a space between the MOSFETs Tr1 and Tr3, a space between the MOSFETs Tr6 and Tr8, a space between the MOSFETs Tr11 and Tr13, and a space between the MOSFETs Tr16 and Tr18 are broadened. As a result, the pattern density difference in the gate electrodes is caused, which brings about a fluctuation in the film thicknesses T1 to T4 of the spacers 12, 12′, 15, and 15′ in the integrated circuits 2₁, 2₂, 3₁ and 3₂.

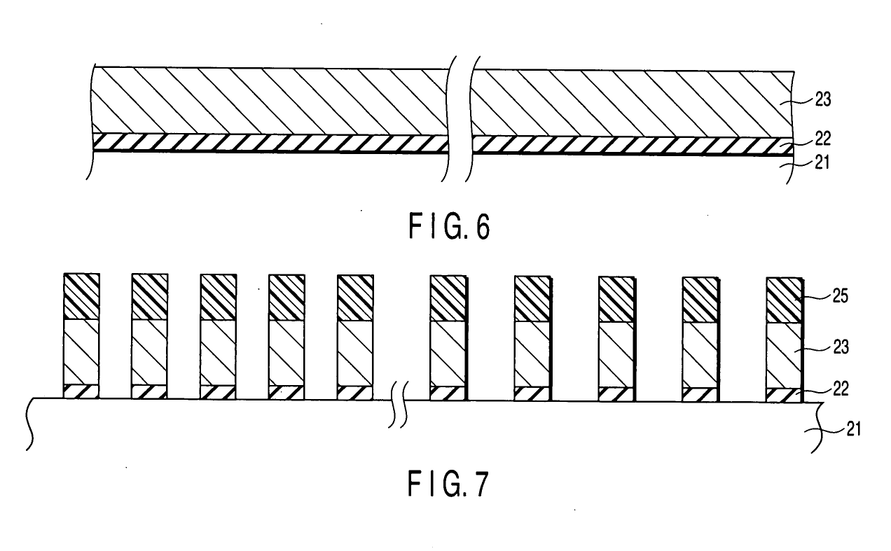

Next, a manufacturing method for the semiconductor device of the preset embodiment will be described with reference to FIGS. 6 to 12.

First, as shown in FIG. 6, an insulating film 22 whose thickness is Tox1 and a conducting film 23 such as a polycrystalline silicon film or the like including impurities are successively formed on a silicon substrate 21. At that time, as shown in FIG. 10, the insulating film 22 and the conducting film 23 are formed in a state that the regions of the integrated circuits 22 and 32 are covered with a resist 24. After the insulating film 22 and the conducting film 23 are formed, the resist 24 is removed.

Next, as shown in FIG. 7, a resist pattern 25 is formed on the conducting film 23, and thereafter, the conducting film 23 and the insulating film 22 are etched by RIE process by using the resist pattern 25 as a mask, thereby gate electrodes 23 and gate insulating films 22 are formed. After the gate electrodes 23 and the gate insulating films 22 are formed, the resist pattern 25 is removed.

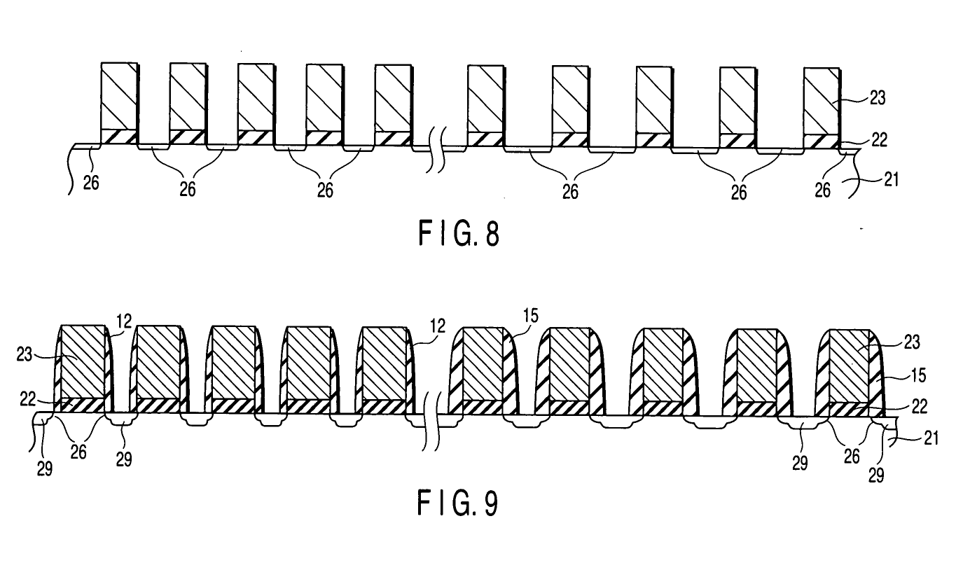

Next, as shown in FIG. 8, ion implantations of n-type and p-type impurity ions are carried out by using the gate electrodes 23 as a mask, and thereafter, extensions 26 are formed by annealing. At this time, the implantation of n-type impurity ions is, as shown in FIG. 11, carried out in a state that the regions of the integrated circuits 2₂, 3₁, and 3₂ are covered with a resist 27. On the other hand, the implantation of p-type impurity ions is, as shown in FIG. 12, carried out in a state that the regions of the integrated circuits 2₁, 2₂, and 3₂ are covered with a resist 28.

Next, as shown in FIG. 9, insulating film to be the spacers 12 and 15 is deposited so as to cover the top surface and the side surface of the gate section (the gate insulating films 22 and the gate electrodes 23) by LPCVD process, and thereafter, the spacers 12 and 15 are formed by etching the insulating films by RIE process.

Next, as shown in FIG. 9, ion implantations of n-type and p-type impurity ions are carried out by using the spacers 12 and 15, and the gate insulating films 22 as a mask, and thereafter, sources/drains 29 are formed by annealing. The ion implantations are carried out in the same way as the ion implantations for forming the extensions 26. That is, the resists 27 and 28 are formed such that the predetermined impurity ions are selectively implanted into the regions of predetermined integrated circuits.

The n-channel and p-channel type MOSFETs in the integrated circuit 2₁ and the integrated circuit 3₁ in which the film thicknesses of the gate oxide films are Tox1(=Tox3) are obtained via the above processes. The n-channel and p-channel type MOSFETs in the integrated circuit 2₂ and the integrated circuit 3₂ in which the film thicknesses of the gate oxide films are Tox2(=Tox4) are obtained via the same processes.

The integrated circuits 2₁, 3₁ in which the film thicknesses of the gate oxide films are Tox1, and the integrated circuits 2₂, 3₂ in which the film thicknesses of the gate oxide films are Tox2 are obtained even by the following process (Multi-Oxied Process).

First, a thick gate insulating film is formed on the silicon substrate 21.

Next, the thick gate insulating film on the region of the integrated circuits 2₂, 3₂ is removed by etching the thick gate insulating film in a state that the region of the integrated circuits 2₁, 3₁ are covered with resist

Next, a thin gate insulating film is formed on regions including the integrated circuits 2₁, 2₂, 3₁, 3₂.

The gate insulating film (=the thick gate insulating film+the thin gate insulating film) on the regions of the integrated circuits 2₁, 3₁ is thicker than the gate insulating film (=the thin gate insulating film) on the regions of the integrated circuits 2₂, 3₂ by the thick gate insulating film).

The thicknesses of the thick gate insulating film and the thin gate insulating film are selected such that the gate insulating films on the integrated circuits 2₁, 3₁ are to be Tox1 and the gate insulating films on the integrated circuits 2₂, 3₂ are to be Tox2.

Thereafter, the gate electrodes, extensions, and source/drain regions are formed by conventional process.

Thereafter, a process for constructing the circuits by connecting the MOSFETs in the respective integrated circuits with wirings is followed. At this time, the MOSFETs Tr2, 7, 12, and 17 are made dummy MOSFETs by disconnecting the MOSFETs Tr2, 7, 12, and 17 electrically to other MOSFETs. Or, the MOSFETs Tr2, 7, 12, and 17 are made dummy MOSFETs by omitting extensions and source/drain regions in the MOSFETs Tr2, 7, 12, and 17. Such dummy MOSFETs can be easily realized by forming a resist such that the ions are not implanted into the regions of the dummy MOSFETs in the process of ion implantations for forming extensions and source/drain regions.

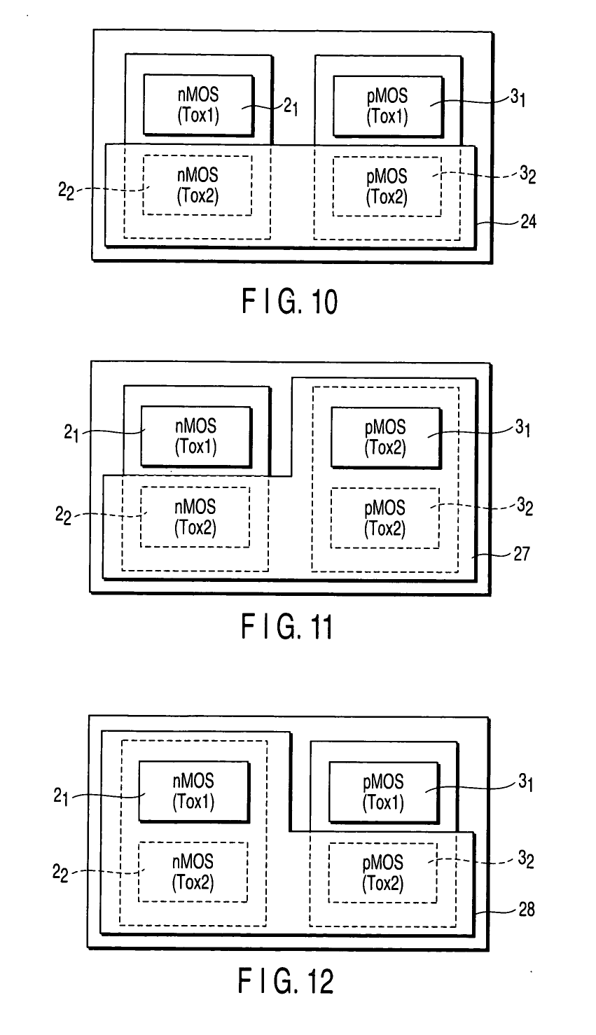

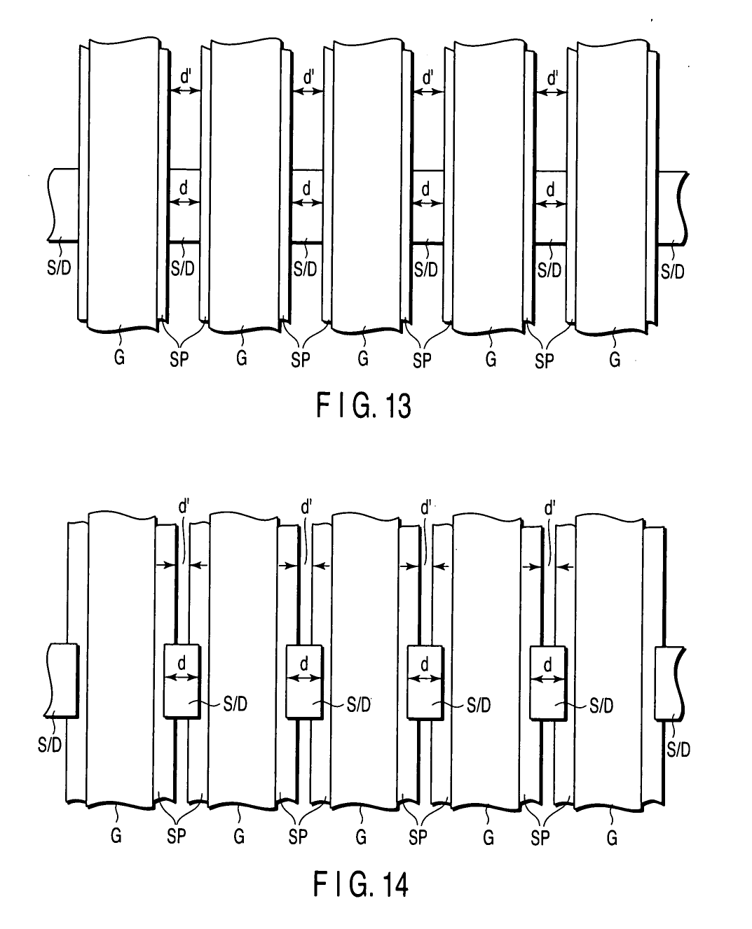

The plan views of the MOSFETs in the integrated circuits of the present embodiment are shown in FIG. 13 and FIG. 14.

In the drawings, G denote gate electrodes, SP denote spacers, S/D denote source/drain regions, d denote distances between the spacers on the active region (element region), and d′ denote distances between the spacers on the isolation region. In the drawings, the MOSFETs in the integrated circuits 2₁, 2₂, 3₁ and 3₂ are not discriminated from one another.

FIG. 13 shows a plan view in a case of d=d′, and FIG. 14 shows a plan view in a case of d≠d′. In a semiconductor manufacturing process, in particular, from the standpoint of a lithography process, as shown in FIG. 13, there is the advantage in the case in which the distances between the spacers are constant regardless of a place.

Next, another embodiment will be described. The semiconductor device of the present embodiment does not include dummy MOSFETs (dummy gate electrode portion). The spacers provided on sidewalls of the MOSFETs have thickness corresponding to the kind (characteristic) of the MOSFETs.

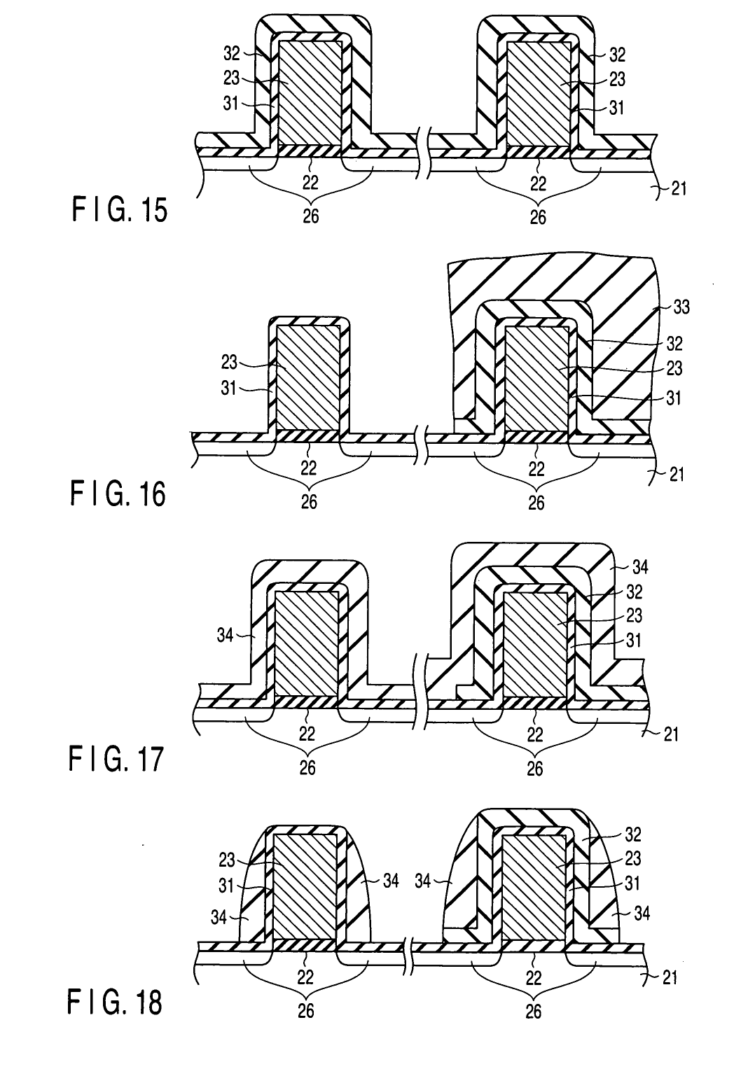

FIGS. 15 to 18 are cross-sectional views showing the manufacturing method for the semiconductor device of the present embodiment.

In the FIGS. 15 to 18, the left side shows a MOSFET (first MOSFET) in the first nMOS integrated circuit 2₁, the right side shows a MOSFET (second MOSFET) in the first pMOS integrated circuit 3₁. Each of the integrated circuits 2₁, 3₁ includes a plurality of MOSFET, however, for simplicity, only one MOSFET in the each of the integrated circuits 2₁, 3₁ is shown in the FIGS. 15 to 18.

First, the aforementioned steps of FIGS. 6 and 8 are carried out.

Next, as shown in FIG. 15, an insulating film 31 is formed on the entire region. Here, the insulating film 31 is a silicon nitride film.

Next, as shown in FIG. 16, an insulating film 32 is formed on the insulating film 31, thereafter, in a state that the first pMOS integrated circuit 3₁ is covered with resist 33, the insulating film 32 is etched by RIE process. Wet etching, which is isotropic etching, is better than RIE process. As the result, the insulating film 32 on the first nMOS integrated circuit 2₁ is removed. Here, by using a BSG film as the insulating film 32, the insulating film 32 can be etched in condition that the etching rate of the insulating film 32 is sufficiently higher than the etching rate of the insulating film 31. Therefore, the surface of the silicon substrate 21 is not exposed. That is, the substrate damage is suppressed.

Next, the resist 33 is removed, thereafter, as shown in FIG. 17, an insulating film 34 is formed on the entire region. Here the insulating film 34 is a silicon nitride film.

Next, as shown in FIG. 18, the insulating film 34 is etched by RIE process. As the result, a spacer 33 is formed on the gate sidewall of the first MOSFET (left side), and spacers 32, 33 are formed on the gate sidewall of second MOSFET (right side).

Thickness of the spacer 33 of the first MOSFET is T1, thickness of the spacers 32, 33 is T3 (>T1). The thickness of the insulating films 31-33 is selected such that the thickness T1, T2 can be obtained.

Thereafter, source/drain regions are formed as in the same way as the FIG. 9, further, the process for constructing the circuits by connecting the MOSFETs in the respective integrated circuits with wirings is followed.

As in the same way as the present embodiment, the MOSFET in the second nMOS integrated circuit 2₂ and the MOSFET in the second pMOS integrated circuit 3₂ can be formed (in a case of different channel types).

Further, the MOSFET in the first nMOS integrated circuit 2₁ and the MOSFET in the first pMOS integrated circuit 3₁, or the MOSFET in the second nMOS integrated circuit 2₂ and the MOSFET in the second pMOS integrated circuit 3₂ can be formed (in a case of different power supply voltages). In this case, the MOSFET for the higher power supply voltage includes the thicker gate insulating film than the MOSFET for the lower power supply voltage.

Further, the MOSFET in the first nMOS integrated circuit 2₁ and the MOSFET in the first PMOS integrated circuit 3₁, and the MOSFET in the second nMOS integrated circuit 2₂ and the MOSFET in the second pMOS circuit 3₂ can be formed (in a case of different channel types and power supply voltages).

The present embodiment is not limited to the above specific example. That is, it may be performed, if each of the thicknesses of the spacers is different for each of a plurality of MOSFET line-ups which are subjected to the present invention.

In the embodiments, the present invention is applied to the integrated circuits which do not include a memory and a peripheral circuit thereof, however, the present invention is applicable to an integrated circuit which includes a memory and a peripheral circuit such as a cache memory including a memory (SRAM) and a peripheral circuit, or an embedded DREAM including a DRAM and a peripheral circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a first integrated circuit provided on the semiconductor substrate, the first integrated circuit comprising a first MOSFET, a second MOSFET disposed at one side of the first MOSFET, and a third MOSFET disposed at other side of the first MOSFET, the first, second, and third MOSFETs having same channel type, and each of the first, second, and third MOSFETs including gate electrode and gate sidewall insulating film provided on a sidewall of the gate electrode, and a distance between the gate electrodes of the first and second MOSFETs, and a distance between the gate electrodes of the first and third MOSFETs being same first distance; and
a second integrated circuit provided on the semiconductor substrate, the second integrated circuit comprising a fourth MOSFET of which at least one of a film thickness of a gate insulating film and a channel type is different from those of the first MOSFET, a fifth MOSFET disposed at one side of the fourth MOSFET, and a sixth MOSFET disposed at other side of the fourth MOSFET, the fourth, fifth, and sixth MOSFETs having the same channel type, and each of the fourth, fifth, and sixth MOSFETs including gate electrode and gate sidewall insulating film provided on sidewall of gate electrode, and a distance between the gate electrodes of the fourth and fifth MOSFETs, and a distance between the gate electrodes of the fourth and sixth MOSFETs being same second distance which is different from the first distance.

2. The semiconductor device according to claim 1,
wherein the first and second integrated circuits are integrated circuits in a system LSI, and failed to include a memory cell circuit and a peripheral circuit thereof.

3. The semiconductor device according to claim 1,
wherein the first and second integrated circuits are logic ICs or ASICs.

4. The semiconductor device according to claim 2,
wherein the first and second integrated circuits are logic ICs or ASICs.

5. The semiconductor device according to claim 1,
wherein part of the first, second, and third MOSFETs is dummy transistor which fails to carry out transistor operation, and part of the fourth, fifth, and sixth MOSFETs is dummy transistor which fails to carry out transistor operation.

6. The semiconductor device according to claim 2,
wherein part of the first, second, and third MOSFETs is dummy transistor which fails to carry out transistor operation, and part of the fourth, fifth, and sixth MOSFETs is dummy transistor which fails to carry out transistor operation.

7. The semiconductor device according to claim 3,
wherein part of the first, second, and third MOSFETs is dummy transistor which fails to carry out transistor operation, and part of the fourth, fifth, and sixth MOSFETs is dummy transistor which fails to carry out transistor operation.

8. The semiconductor device according to claim 4,
wherein part of the first, second, and third MOSFETs is dummy transistor which fails to carry out transistor operation, and part of the fourth, fifth, and sixth MOSFETs is dummy transistor which fails to carry out transistor operation.

9. The semiconductor device according to claim 1,
wherein the gate sidewall insulating films of the first, second, and third MOSFETs have same first film thickness, and the gate sidewall insulating films of the fourth, fifth, and sixth MOSFETs have same second film thickness, and the first film thickness and the second film thickness are different from one another.

10. The semiconductor device according to claim 2,
wherein the gate sidewall insulating films of the first, second, and third MOSFETs have same first film thickness, and the gate sidewall insulating films of the fourth, fifth, and sixth MOSFETs have the second film thickness, and the first film thickness and the second film thickness are different from one another.

11. The semiconductor device according to claim 3,
wherein the gate sidewall insulating films of the first, second, and third MOSFETs have same first film thickness, and the gate sidewall insulating films of the fourth, fifth, and sixth MOSFETs have same second film thickness, and the first film thickness and the second film thickness are different from one another.

12. The semiconductor device according to claim 4,
wherein the gate sidewall insulating films of the first, second, and third MOSFETs have same first film thickness, and the gate sidewall insulating films of the fourth, fifth, and sixth MOSFETs have same second film thickness, and the first film thickness and the second film thickness are different from one another.

13. The semiconductor device according to claim 1,
wherein the first integrated circuit is part of integrated circuits in a system LSI, and includes a memory cell circuit and peripheral circuit thereof.

14. The semiconductor device according to claim 13,
wherein the memory cell circuit and peripheral circuit thereof is included in a cache memory comprising an SRAM.

15. The semiconductor device according to claim 13,
wherein the memory cell circuit and peripheral circuit thereof is included in an embedded DRAM.

16. A semiconductor device comprising:
a semiconductor substrate;
an integrated circuit provided on the semiconductor substrate, the integrated circuit comprising a first line-up of first MOSFETs each having a first characteristic and a second line of second MOSFETs each having a second characteristic which is different from the first characteristic, each of the first and second MOSFETs includes gate electrode and gate sidewall insulating film provided on a sidewall of the gate electrode, the gate sidewall insulating film of the first MOSFET having a thickness corresponding to the first characteristic, and the gate sidewall insulating film of the second MOSFET having a thickness corresponding to the second characteristic.

17. The semiconductor device according to claim 16,
wherein each the first MOSFETs is different from each the second MOSFETs in at least one of thickness of gate insulating film and channel type.

18. The semiconductor device according to claim 16,
wherein the integrated circuit comprises a first integrated circuit and a second integrated circuit, the first integrated circuit includes the first MOSFETs, and the second integrated circuit includes the second MOSFETs.

19. The semiconductor device according to claim 18,
wherein a power supply voltage of the first MOSFETs is higher than a power supply voltage of the second MOSFETs.

20. The semiconductor device according to claim 18,
wherein gate insulating films of the first MOSFETs are thicker than gate insulating films of the second MOSFETs.
